(19) United States
(12) Patent Application Publication
(10) Pub. No.: US 2025/0163267 A1
(43) Pub. Date: May 22, 2025

(54) THERMOSETTING RESIN COMPOSITION, PREPREG, RESIN FILM, LAMINATE, PRINTED WIRING BOARD, ANTENNA DEVICE, ANTENNA MODULE AND COMMUNICATION DEVICE

(71) Applicant: RESONAC CORPORATION, Tokyo (JP)

(72) Inventors: Masashi OJI, Tokyo (JP); Yuichi SHIMAYAMA, Tokyo (JP); Koji MORITA, Tokyo (JP); Kosuke MURAI, Tokyo (JP); Masaki YAMAGUCHI, Tokyo (JP)

(21) Appl. No.: 18/729,013

(22) PCT Filed: Dec. 22, 2022
(86) PCT No.: PCT/JP2022/047277

§ 371 Date: Jul. 15, 2024

(30) Foreign Application Priority Data
Jan. 26, 2022 (JP) 2022-010322

(51) Int. Cl. C08L 71/12; C08J 5/18; C08J 5/24; C08K 3/22; C08K 3/36; C08K 5/315; C08K 5/3445; C08K 5/521; C08K 7/18; C09D 155/00; H01Q 1/38; H05K 1/03

(52) U.S. Cl. CPC C08L 71/126; C08J 5/18; C08J 5/244; C08K 3/36; C08K 5/3155; C08K 5/3445; C08K 5/521; C08K 7/18; H01Q 1/38; H05K 1/0373; C08J 2371/12; C08J 2479/08; C08K 2003/2206; C08K 2003/2241; C08K 2201/005; C08L 2203/16; C08L 2203/20; C08L 2205/03; C09D 155/005; H05K 2201/0209; H05K 2201/0266

(57) ABSTRACT

To provide a thermosetting resin composition which is useful for an antenna module capable of coping with a signal in a high-frequency band and having excellent mesh passability. Specifically disclosed is a thermosetting resin composition containing (A) a thermosetting resin and (B) at least one inorganic filler selected from the group consisting of a titanium-based inorganic filler and a zircon-based inorganic filler, in which in the component (B), a content of particles having a particle diameter of 1.0 μm or less is 30% by volume or less based on the component (B). And to provide a prepreg, a resin film, a laminate, a printed wiring board, an antenna device, an antenna module, and a communication device obtained by using the thermosetting resin composition.

### TECHNICAL FIELD

The present disclosure relates to a thermosetting resin composition, a prepreg, a resin film, a laminate, a printed wiring board, an antenna device, an antenna module, and a communication device.

### BACKGROUND ART

In recent years, mobile terminals such as smartphones have become popular, and as a result of technological innovation such as the Internet of Things (IoT), home appliances and electronic devices having a wireless communication function have increased. This raises a concern that the communication traffic of the wireless network increases and the communication speed and the communication quality are reduced.

In order to solve the problem, the development of the Fifth Generation Mobile Communication System (hereinafter, sometimes referred to as “5G”) is in progress, and the 5G system is already being used. In 5G, advanced beam forming and spatial multiplexing are performed using a plurality of antenna elements, and in addition to signals of frequencies in the 6 GHz band that have been used conventionally, signals of millimeter wave bands with higher frequencies such as several tens of GHz are used. Accordingly, it is expected that the communication speed is increased and the communication quality is improved. Hereinafter, a frequency of 10 GHz or higher is referred to as a high frequency.

As described above, in 5G, it is necessary for the antenna module to be capable of coping with high-frequency signals, and for this purpose, it is required that the dielectric constant (Dk) and the dielectric dissipation factor (Df) of the laminate in a high-frequency band be low, and in particular, that the dielectric dissipation factor (Df) be low.

Since radio waves of high frequencies have high linearity, signals carried on radio waves of high frequencies tend to be easily blocked by obstacles such as buildings. Therefore, in order to avoid the blocking, a plurality of antenna devices are mounted on the antenna module. Since the antenna device can be downsized by increasing the dielectric constant (Dk) of a substrate material, increasing the dielectric constant (Dk) is effective for mounting a plurality of antenna devices, and leads to downsizing of the antenna module, which in turn leads to downsizing of the communication device. Therefore, the laminate used in the antenna module that is capable of coping with high-frequency signals is required to have a dielectric constant (Dk) of a predetermined height and a low dielectric dissipation factor (Df).

Here, as one of the methods for increasing the dielectric constant (Dk) of the substrate material, a method using a high dielectric constant material is mentioned (for example, refer to PTL 1). The small antenna described in PTL 1 is produced by laminating and forming a first dielectric layer made of a low dielectric constant material between second and third dielectric layers made of a high dielectric constant material.

### CITATION LIST

### Patent Literature

PTL 1: WO 2005/101574

### SUMMARY OF INVENTION

### Technical Problem

A thermosetting resin composition used for an antenna device, a printed wiring board, and the like is generally used after being filtered with a mesh having a predetermined mesh size in order to remove a metal foreign substance and the like which may cause insulation failure. Therefore, when the present inventors prepared a varnish of a thermosetting resin composition containing various high dielectric constant materials and then filtered the varnish using a #200 mesh (mesh size: 75 μm), it was found that clogging sometimes occurred. If the amount of the varnish is small, it is possible to filter out the varnish by pressing the varnish from above using a spatula or the like, but when this is carried out on an industrial scale, it is difficult to cope with this, and the practice may be impossible. Hereinafter, when the varnish of the thermosetting resin composition is filtered using a mesh, the ease of passing through the mesh is referred to as “mesh passability”.

In view of such a current situation, the present disclosure aims to provide a thermosetting resin composition useful for an antenna module capable of coping with a signal in a high-frequency band and having excellent mesh passability, and to provide a prepreg, a resin film, a laminate, a printed wiring board, an antenna device, an antenna module, and a communication device obtained by using the thermosetting resin composition.

### Solution to Problem

As a result of intensive studies, the present inventors have found that the object can be achieved by the thermosetting resin composition of the present disclosure.

The present disclosure includes the following [1] to [16].

[1] A thermosetting resin composition containing:
(A) a thermosetting resin; and
(B) at least one inorganic filler selected from the group consisting of a titanium-based inorganic filler and a zircon-based inorganic filler, in which in the component (B), a content of particles having a particle diameter of 1.0 μm or less is 30% by volume or less based on the component (B).

[2] The thermosetting resin composition according to [1], in which a content of particles having a particle diameter of 1.0 μm in the component (B) is 4.5% by volume or less based on the component (B).

[3] The thermosetting resin composition according to [1] or [2], in which the component (B) has an average particle diameter of 1.0 μm or more.

[4] The thermosetting resin composition according to any one of [1] to [3], in which the titanium-based inorganic filler is at least one selected from the group consisting of titanium dioxide and a metal titanate.

[5] The thermosetting resin composition according to [4], in which the metal titanate is at least one selected from the group consisting of an alkali metal titanate, an alkaline earth metal titanate, and lead titanate.

[6] The thermosetting resin composition according to any one of [1] to [5], in which the zircon-based inorganic filler is an alkali metal zirconate.

[7] The thermosetting resin composition according to any one of [1] to [6], in which the content of the component (B) is 1 to 60% by volume with respect to the total solid content in the thermosetting resin composition.

[8] The thermosetting resin composition according to any one of [1] to [7], in which the component (A) contains at least one selected from the group consisting of an epoxy resin, a maleimide compound, a polyphenylene ether resin, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

[9] The thermosetting resin composition according to any one of [1] to [8], in which the component (A) contains a polyphenylene ether resin having ethylenically unsaturated bond-containing groups at both terminals.

[10] A prepreg containing the thermosetting resin composition according to any one of [1] to [9] or a semi-cured product of the thermosetting resin composition.

[11] A resin film containing the thermosetting resin composition according to any one of [1] to [9] or a semi-cured product of the thermosetting resin composition.

[12] A laminate including a cured product of the thermosetting resin composition according to any one of [1] to [9] or a cured product of the prepreg according to [10], and a metal foil.

[13] A printed wiring board including one or more selected from the group consisting of a cured product of the thermosetting resin composition according to any one of [1] to [9], a cured product of the prepreg according to [10], and the laminate according to [12].

[14] An antenna device including the laminate according to or the printed wiring board according to [13].

[15] An antenna module including a feeding circuit, and the antenna device according to [14].

[16] A communication device including a baseband signal processing circuit and the antenna module according to [15].

### Advantageous Effects of Invention

According to the present disclosure, it is possible to provide a thermosetting resin composition useful for an antenna module capable of coping with a signal in a high-frequency band and having excellent mesh passability, and to provide a prepreg, a resin film, a laminate, a printed wiring board, an antenna device, an antenna module, and a communication device obtained by using the thermosetting resin composition.

### DESCRIPTION OF EMBODIMENTS

In the numerical range described in the description herein, the upper limit value or the lower limit value of the numerical range may be replaced with a value shown in Examples. In addition, the lower limit value and the upper limit value of the numerical range are arbitrarily combined with the lower limit value or the upper limit value of another numerical range, respectively. In the notation of the numerical range “AA to BB”, the numerical values AA and BB at both ends are included in the numerical range as the lower limit value and the upper limit value, respectively.

In the description herein, for example, the description of “10 or more” means 10 and a numerical value exceeding 10, and the same applies to a case where the numerical value is different. Further, for example, the description of “10 or less” means 10 and a numerical value less than 10, and the same applies to a case where the numerical value is different.

In addition, each component and material exemplified in the description herein may be used alone or in combination of two or more kinds thereof, unless otherwise specified. In the description herein, when a plurality of substances corresponding to each component are present in a composition, the content of each component in the composition means the total amount of the plurality of substances present in the composition, unless otherwise specified.

In the description herein, the “resin component” refers to all components except for inorganic compounds such as a high dielectric constant inorganic filler and an inorganic filler to be described later among solid contents constituting the resin composition.

In the description herein, the “solid content” refers to a component in the resin composition other than an organic solvent to be described later. That is, the solid content also includes those in a liquid state, a syrup state, or a wax state at room temperature around 25° C. in addition to those in a solid state at room temperature around 25° C.

The expression “containing XX” described in the description herein naturally includes containing XX, but also includes containing XX in a reacted state.

An aspect in which matters described in the description herein are arbitrarily combined is also included in the present disclosure and the present embodiment.

### [Thermosetting Resin Composition]

The thermosetting resin composition of the present embodiment is as follows.

A thermosetting resin composition containing:
(A) a thermosetting resin [hereinafter, sometimes referred to as component (A)]; and
(B) at least one inorganic filler selected from the group consisting of a titanium-based inorganic filler and a zircon-based inorganic filler [hereinafter, sometimes referred to as component (B) or a high dielectric constant inorganic filler],
in which in the component (B), a content of particles having a particle diameter of 1.0 μm or less is 30% by volume or less based on the component (B).

Here, in the present disclosure, “based on the component (B)” means based on the total sum of all particles of the component (B).

Hereinafter, the components contained in the thermosetting resin composition of the present embodiment will be described in detail in order.

### ((A) Thermosetting Resin)

Examples of the component (A) include an epoxy resin, a maleimide compound, a polyphenylene ether resin, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Among these, as the component (A), an epoxy resin, a maleimide compound, and a polyphenylene ether resin are preferable, and a maleimide compound and a polyphenylene ether resin are more preferable from the viewpoint of low thermal expansion properties and high-frequency characteristics.

As the component (A), one type may be used alone, or two or more types may be used in combination.

The epoxy resin is preferably an epoxy resin having two or more epoxy groups in one molecule. Here, the epoxy resin is classified into a glycidyl ether type epoxy resin, a glycidyl amine type epoxy resin, a glycidyl ester type epoxy resin, and the like. Among these, a glycidyl ether type epoxy resin is preferable.

Epoxy resins are classified into various epoxy resins according to the difference in the main skeleton, and in each of the above types of epoxy resins, epoxy resins are further classified into bisphenol type epoxy resins such as bisphenol A type epoxy resin, bisphenol F type epoxy resin, and bisphenol S type epoxy resin; alicyclic epoxy resins such as dicyclopentadiene type epoxy resin; aliphatic chain epoxy resins; novolac type epoxy resins such as phenol novolac type epoxy resin, cresol novolac type epoxy resin, bisphenol A novolac type epoxy resin, bisphenol F novolac type epoxy resin, phenol aralkyl novolac type epoxy resin, and biphenyl aralkyl novolac type epoxy resin; stilbene type epoxy resins; naphthalene skeleton-containing epoxy resins such as naphthol novolac type epoxy resin and naphthol aralkyl type epoxy resin; biphenyl type epoxy resins; xylylene type epoxy resins; and dihydroanthracene type epoxy resins.

The maleimide compound preferably includes at least one selected from the group consisting of maleimide compounds having one or more (preferably two or more) N-substituted maleimide groups and derivatives thereof.

Examples of the maleimide compound having one or more N-substituted maleimide groups include, but are not particularly limited to, aromatic maleimide compounds having one N-substituted maleimide group preferably bonded to an aromatic ring, such as N-phenylmaleimide, N-(2-methylphenyl) maleimide, N-(4-methylphenyl) maleimide, N-(2,6-dimethylphenyl) maleimide, N-(2,6-diethylphenyl) maleimide, N-(2-methoxyphenyl) maleimide, and N-benzylmaleimide; aromatic bismaleimide compounds having two N-substituted maleimide groups preferably bonded to an aromatic ring, such as bis(4-maleimidophenyl) methane, bis(4-maleimidophenyl) ether, bis(4-maleimidophenyl) sulfone, 3,3′-dimethyl-5,5′-diethyl-4,4′-diphenylmethane bismaleimide, 4-methyl-1,3-phenylene bismaleimide, m-phenylene bismaleimide, 2,2-bis [4-(4-maleimidophenoxy)phenyl]propane, and indane ring-containing bismaleimide; aromatic polymaleimide compounds having three or more N-substituted maleimide groups preferably bonded to an aromatic ring, such as polyphenylmethane maleimide and biphenyl aralkyl type maleimide; and aliphatic maleimide compounds such as N-dodecylmaleimide, N-isopropylmaleimide, N-cyclohexylmaleimide, 1,6-bismaleimido-(2,2,4-trimethyl) hexane, and a pyrophosphoric acid binder type long chain alkyl bismaleimide. Among these, from the viewpoint of compatibility with other resins, adhesiveness to a conductor, heat resistance, low thermal expansion properties, and mechanical properties, an aromatic bismaleimide compound having two N-substituted maleimide groups preferably bonded to an aromatic ring is more preferable, and 2,2-bis [4-(4-maleimidophenoxy)phenyl]propane is still more preferable.

Examples of the derivative of the maleimide compound include an addition reaction product of the maleimide compound having one or more (preferably two or more) N-substituted maleimide groups and an amine compound such as a monoamine compound and a diamine compound (hereinafter, sometimes referred to as a “modified maleimide compound”). Examples of the monoamine compound include monoamine compounds having an acidic substituent, such as o-aminophenol, m-aminophenol, p-aminophenol, o-aminobenzoic acid, m-aminobenzoic acid, p-aminobenzoic acid, o-aminobenzenesulfonic acid, m-aminobenzenesulfonic acid, p-aminobenzenesulfonic acid, 3,5-dihydroxyaniline, and 3,5-dicarboxyaniline. Examples of the diamine compound include 4,4′-diaminodiphenylmethane, 4,4′-diaminodiphenylethane, 4,4′-diaminodiphenylpropane, 2,2′-bis(4,4′-diaminodiphenyl) propane, 3,3′-dimethyl-4,4′-diaminodiphenylmethane, 3,3′-diethyl-4,4′-diaminodiphenylmethane, 3,3′-dimethyl-4,4′-diaminodiphenylethane, 3,3′-diethyl-4,4′-diaminodiphenylethane, 4,4′-diaminodiphenyl ether, 4,4′-diaminodiphenyl thioether, 3,3′-dihydroxy-4,4′-diaminodiphenylmethane, 2,2′,6,6′-tetramethyl-4,4′-diaminodiphenylmethane, 3,3′-dichloro-4,4′-diaminodiphenylmethane, 3,3′-dibromo-4,4′-diaminodiphenylmethane, 2,2′,6,6′-tetrachloro-4,4′-diaminodiphenylmethane, 2,2′,6,6′-tetrabromo-4,4′-diaminodiphenylmethane, and siloxane diamine.

The maleimide compound preferably includes an addition reaction product of a maleimide compound having two or more N-substituted maleimide groups and an amine compound, and more preferably includes an addition reaction product of a maleimide compound having two or more N-substituted maleimide groups and a diamine compound including a siloxane diamine.

The polyphenylene ether resin may be an unmodified polyphenylene ether resin or a polyphenylene ether resin having an ethylenically unsaturated bond-containing group at the terminal, and the latter is preferred. The polyphenylene ether resin having an ethylenically unsaturated bond-containing group at the terminal is preferably a polyphenylene ether resin having an ethylenically unsaturated bond-containing group at both terminals. Here, the “ethylenically unsaturated bond-containing group” means a substituent containing a carbon-carbon double bond capable of an addition reaction, and does not include a double bond of an aromatic ring. Examples of the ethylenically unsaturated bond-containing group include unsaturated aliphatic hydrocarbon groups such as a vinyl group, an allyl group, a 1-methylallyl group, an isopropenyl group, a 2-butenyl group, a 3-butenyl group, and a styryl group; and groups containing a hetero atom and an ethylenically unsaturated bond, such as a maleimide group and a (meth)acryloyl group. As the ethylenically unsaturated bond-containing group, a group containing a hetero atom and an ethylenically unsaturated bond is preferable, a (meth)acryloyl group is more preferable, and a methacryloyl group is still more preferable.

In the description herein, the “(meth)acryloyl group” means an acryloyl group or a methacryloyl group.

### (Content of Component (A))

The content of the thermosetting resin (A) in the thermosetting resin composition of the present embodiment is not particularly limited, but is preferably 5 to 95 parts by mass, more preferably 10 to 80 parts by mass, still more preferably 10 to 60 parts by mass, and particularly preferably 15 to 40 parts by mass, with respect to 100 parts by mass of the total solid content in the thermosetting resin composition from the viewpoint of high-frequency characteristics, heat resistance, and moldability.

((B) at Least One Inorganic Filler Selected from the Group Consisting of a Titanium-Based Inorganic Filler and a Zircon-Based Inorganic Filler)

In the component (B) used in the present embodiment, the content of particles having a particle diameter of 1.0 μm or less is 30% by volume or less based on the component (B). This makes it possible to effectively suppress clogging when the varnish of the thermosetting resin composition is passed through a #200 mesh (mesh size: 75 μm), and thus the present invention can be carried out on an industrial scale. In the description herein, the particle diameter refers to a primary particle diameter. The content of particles having a particle diameter of 1.0 μm or less means the total content of particles having a particle diameter of 1.0 μm or less.

The reason why such an effect is obtained is not clear, but is considered as follows. Since it is not easy to perform surface treatment on a high dielectric constant inorganic filler such as a metal titanate, a surface untreated product is generally available at present. Since many functional groups such as a hydroxy group are present on the surface of the surface-untreated metal titanate, the specific surface area increases when the particle diameter is small, and the interaction with the resin varnish increases, so that it is assumed that the high dielectric constant inorganic filler is aggregated to form an aggregate having a size of 75 μm or more. There is a possibility that the aggregation can be suppressed by performing a surface treatment of the high dielectric constant inorganic filler, but this method is industrially disadvantageous from the viewpoint of the production cost.

From the viewpoint of mesh passability, the content of particles having a particle diameter of 1.0 μm or less in the component (B) is preferably 28% by volume or less, and more preferably 25% by volume or less, based on the component (B). The lower limit value of the content of the particles having a particle diameter of 1.0 μm or less is not particularly limited, and may be 0% by volume, may be 5% by volume or more, may be 10% by volume or more, and may be 15% by volume or more.

From the above, in the component (B), the content of the particles having a particle diameter of 1.0 μm or less is preferably 0 to 30% by volume based on the component (B), and the lower limit value and the upper limit value in the numerical range can be changed based on the above description.

The method for measuring the content of particles having a particle diameter of 1.0 μm or less in the component (B) is not particularly limited, but the content can be determined from the cumulative frequency of particles having a particle diameter of 1.0 μm or less by analyzing the particle size distribution of the component (B) using a particle size distribution measuring apparatus. The method and conditions for analyzing the particle size distribution particularly may be in accordance with the method described in Examples. In addition, by observing a cross section of the cured product of the thermosetting resin composition with a microscope and classifying the particles in the image according to the particle diameter, the proportion of particles having a particle diameter of 1.0 μm or less can be calculated, and the content of particles having a particle diameter of 1.0 μm or less in the component (B) can be grasped.

In addition, from the viewpoint of mesh passability, the content of particles having a particle diameter of 1.0 μm in the component (B) is preferably 4.5% by volume or less, more preferably 4% by volume or less, still more preferably 3.5% by volume or less, and particularly preferably 3.4% by volume or less, although not particularly limited thereto. The lower limit value of the content of the particles having a particle diameter of 1.0 μm is not particularly limited, and may be 2% by volume or more, may be 2.5% by volume or more, and may be 2.7% by volume or more.

From the above, in the component (B), the content of the particles having a particle diameter of 1.0 μm is preferably 2 to 4% by volume based on the component (B), and the lower limit value and the upper limit value in the numerical range can be changed based on the above description.

The method for measuring the content of particles having a particle diameter of 1.0 μm is not particularly limited, but the content can be determined from the frequency of particles having a particle diameter of 1.0 μm by analyzing the particle size distribution of the component (B) using a particle size distribution measuring apparatus. The method and conditions for analyzing the particle size distribution particularly may be in accordance with the method described in Examples.

The average particle diameter of the component (B) is not particularly limited, but is preferably 1.0 μm or more. When the average particle diameter of the component (B) is 1.0 μm or more, heat resistance is significantly improved. Although the exact reason why such an effect is obtained is not known, it is presumed that after the varnish of the thermosetting resin composition is passed through the mesh, the component (B) in the varnish passed through the mesh aggregates, which affects the decrease in heat resistance. From the same viewpoint, the average particle diameter of the component (B) is preferably 1.3 μm or more, more preferably 1.5 μm or more, and still more preferably 1.8 μm or more. The upper limit value of the average particle diameter of the component (B) is preferably 4.0 μm or less, more preferably 3.5 μm or less, still more preferably 3.0 μm or less, and particularly preferably 2.5 μm or less, from the viewpoint of excluding coarse particles which may cause insulation failure.

From the above, the average particle diameter of the component (B) is preferably 1.0 to 4.0 μm, and the lower limit value and the upper limit value in the numerical range can be changed based on the above description.

The average particle diameter of the component (B) is a d50 value (median diameter of volume distribution) obtained by analyzing the particle size distribution using a particle size distribution measuring apparatus. The method and conditions for analyzing the particle size distribution particularly may be in accordance with the method described in Examples.

The titanium-based inorganic filler is preferably at least one selected from the group consisting of titanium dioxide and a metal titanate from the viewpoint of the dielectric constant (Dk). From the viewpoint of dielectric constant (Dk), examples of the metal titanate include alkali metal titanates such as potassium titanate; alkaline-earth metal titanates such as barium titanate, calcium titanate, and strontium titanate; and lead titanate. The metal titanate is preferably at least one selected from the above examples, more preferably an alkaline-earth metal titanate from the viewpoint of the dielectric constant (Dk), and still more preferably calcium titanate or strontium titanate.

The zircon-based inorganic filler is preferably an alkali metal zirconate from the viewpoint of the dielectric constant (Dk). The alkali metal zirconate is preferably at least one selected from the group consisting of calcium zirconate and strontium zirconate from the viewpoint of the dielectric constant (Dk).

As the component (B), from the viewpoints of dielectric dissipation factor (Df) and specific gravity, a titanium-based inorganic filler is preferable, and more preferable components are as described above.

The shape of the component (B) is not particularly limited, but since industrially available high dielectric constant inorganic fillers generally have an undefined shape in many cases, the shape may be an undefined shape, but may be another shape such as a spherical shape.

The method for producing the component (B) used in the present embodiment is not particularly limited, and examples thereof include a method of classification and a method of adjusting the way of pulverization. In the case of the method of classification, particles having a particle diameter of 1.0 μm or less can be easily reduced by sieving. In addition, in the case of the method of adjusting the way of pulverization, at least one kind of high dielectric constant inorganic filler selected from the group consisting of the titanium-based inorganic filler and the zircon-based inorganic filler is pulverized by a pulverizer such as a ball mill or a jet mill, whereby pulverization can be performed so that particles having a particle diameter of 1.0 μm or less are not generated, and as a result, particles having a particle diameter of 1.0 μm or less can be easily reduced.

### (Content of Component (B))

The content of the component (B) in the thermosetting resin composition of the present embodiment is not particularly limited, but from the viewpoint of the dielectric constant (Dk), the content is preferably 1 to 60% by volume, more preferably 2 to 30% by volume, may be 3 to 20% by volume, may be 7 to 30% by volume, and may be 12 to 25% by volume with respect to the total solid content in the thermosetting resin composition. When the content of the component (B) is described in terms of parts by mass, the content is preferably 5 to 95 parts by mass, more preferably 15 to 90 parts by mass, still more preferably 20 to 70 parts by mass, particularly preferably 20 to 55 parts by mass, and most preferably 25 to 50 parts by mass with respect to 100 parts by mass of the total solid content in the thermosetting resin composition.

In a case where the content of the component (B) in the thermosetting resin composition of the present embodiment is equal to or greater than the lower limit value, there is a tendency that the dielectric constant (Dk) can be sufficiently increased, and in a case where the content thereof is equal to or less than the upper limit value, there is a tendency that the dielectric dissipation factor (Df) can be prevented from being excessively increased.

The thermosetting resin composition of the present embodiment may further contain other components. The other components are not particularly limited, but preferably include one or more selected from the group consisting of (C) an elastomer, (D) an inorganic filler (excluding the component (B)), a coupling agent, (E) a curing accelerator, (F) a flame retardant, a flame retardant aid, an antioxidant, an adhesiveness improving agent, a heat stabilizer, an antistatic agent, an ultraviolet absorber, a pigment, a colorant, and a lubricant.

### ((C) Elastomer)

The thermosetting resin composition of the present embodiment preferably further contains (C) an elastomer, although not particularly limited thereto.

Examples of the elastomer (C) include styrene elastomers, olefin elastomers, urethane elastomers, polyester elastomers, polyamide elastomers, acrylic elastomers, and silicone elastomers. These elastomers are composed of a hard segment component and a soft segment component, and generally, the hard segment component contributes to heat resistance and strength, and the soft segment component contributes to flexibility and toughness.

As the elastomer (C), one type may be used alone, or two or more types may be used in combination.

As the elastomer (C), a styrene elastomer is preferable from the viewpoint of high-frequency characteristics, and a styrene-based thermoplastic elastomer is more preferable. The styrene elastomer may have a structural unit derived from a styrene compound, and from the viewpoint of high-frequency characteristics, adhesiveness to a conductor, heat resistance, and low thermal expansion properties, the styrene elastomer is preferably one or more selected from the group consisting of a hydrogenated product of a styrene-butadiene-styrene block copolymer (SEBS, SBBS), a hydrogenated product of a styrene-isoprene-styrene block copolymer (SEPS), and a styrene-maleic anhydride copolymer (SMA), more preferably one or more selected from the group consisting of a hydrogenated product of a styrene-butadiene-styrene block copolymer (SEBS) and a hydrogenated product of a styrene-isoprene-styrene block copolymer (SEPS), and still more preferably a hydrogenated product of a styrene-butadiene-styrene block copolymer (SEBS).

The styrene elastomer (here, excluding the SMA) may be modified with an acid anhydride such as maleic anhydride, and examples thereof include SEBS modified with an acid anhydride such as maleic anhydride and SEPS modified with an acid anhydride such as maleic anhydride. The acid value of the acid-modified styrene elastomer (excluding the SMA) is not particularly limited, but is preferably 2 to 20 mgCH₃ONa/g, more preferably 5 to 15 mgCH₃ONa/g, and still more preferably 7 to 13 mgCH₃ONa/g.

In the styrene elastomer, the content of the structural unit derived from styrene [hereinafter, sometimes referred to as “styrene content”] is not particularly limited, but is preferably 5 to 80% by mass, more preferably 10 to 75% by mass, still more preferably 15 to 60% by mass, and particularly preferably 20 to 45% by mass, from the viewpoint of high-frequency characteristics, adhesiveness to a conductor, heat resistance, and low thermal expansion properties.

The weight-average molecular weight (Mw) of the styrene elastomer is not particularly limited, but is preferably 12,000 to 1,000,000, more preferably 30,000 to 500,000, still more preferably 50,000 to 120,000, and particularly preferably 70,000 to 100,000. The weight-average molecular weight (Mw) means a value measured by gel permeation chromatography (GPC) in terms of polystyrene.

The melt flow rate (MFR) of the styrene elastomer is not particularly limited, but is preferably 0.1 to 20 g/10 min, more preferably 1 to 15 g/10 min, still more preferably 2 to 10 g/10 min, and particularly preferably 3 to 7 g/10 min under measurement conditions of 230° C. and a load of 2.16 kgf (21.2 N).

### (Content of Elastomer (C))

In a case where the thermosetting resin composition of the present embodiment contains the elastomer (C), the content thereof is not particularly limited, but is preferably 1 to 20 parts by mass, more preferably 2 to 15 parts by mass, and still more preferably 3 to 10 parts by mass with respect to 100 parts by mass of the total solid content in the thermosetting resin composition. When the content of the elastomer (C) is equal to or greater than the lower limit value, more excellent high-frequency characteristics tend to be obtained, and when it is equal to or less than the upper limit value, good heat resistance, moldability, processability and flame retardancy tend to be obtained.

### ((D) Inorganic Filler)

The thermosetting resin composition of the present embodiment preferably further contains (D) an inorganic filler, although not particularly limited thereto.

By containing the inorganic filler (D) in the thermosetting resin composition of the present embodiment, more excellent low thermal expansion properties, high elastic modulus properties, heat resistance, and flame retardancy tend to be obtained. However, the inorganic filler (D) does not contain the component (B).

The inorganic filler (D) can be used alone or in combination of two or more types.

Examples of the inorganic filler (D) include silica, alumina, mica, beryllia, aluminum carbonate, magnesium hydroxide, aluminum hydroxide, aluminum silicate, calcium carbonate, calcium silicate, magnesium silicate, silicon nitride, boron nitride, clay such as calcined clay, molybdic acid compounds such as zinc molybdate, talc, aluminum borate, and silicon carbide. Among these, from the viewpoint of low thermal expansion properties, elastic modulus, heat resistance, and flame retardancy, silica, alumina, mica, and talc are preferable, silica and alumina are more preferable, and silica is still more preferable. Examples of the silica include crushed silica, fumed silica, and fused silica. Among these, fused silica is preferable, and fused spherical silica is more preferable.

The average particle diameter of the inorganic filler (D) is not particularly limited, but is preferably 0.01 to 20 μm, more preferably 0.1 to 10 μm, still more preferably 0.2 to 3 μm, and particularly preferably 0.3 to 1.0 μm.

### (Content of Inorganic Filler (D))

In a case where the thermosetting resin composition of the present embodiment contains the inorganic filler, the content thereof is not particularly limited, but in any case, from the viewpoint of thermal expansion coefficient, elastic modulus, heat resistance, and flame retardancy, the content thereof is preferably 3 to 70% by volume, more preferably 5 to 65% by volume, still more preferably 5 to 60% by volume, even more preferably 10 to 50% by volume, particularly preferably 10 to 40% by volume, and most preferably 10 to 30% by volume with respect to the total solid content in the thermosetting resin composition.

When the content of the component (D) is described in terms of parts by mass, the content is preferably 1 to 60 parts by mass, more preferably 5 to 50 parts by mass, still more preferably 10 to 45 parts by mass, particularly preferably 15 to 45 parts by mass, and most preferably 20 to 40 parts by mass with respect to 100 parts by mass of the total solid content in the thermosetting resin composition.

When the inorganic filler is used, a coupling agent may be used in combination as necessary for the purpose of improving the dispersibility of the inorganic filler and the adhesiveness between the inorganic filler and the organic components in the resin composition. Examples of the coupling agent include a silane coupling agent and a titanate coupling agent. The coupling agent may be used alone or may be used in combination of two or more types.

When the coupling agent is used, the treatment method may be a so-called integral blend treatment method in which the inorganic filler is blended in the resin composition and then the coupling agent is added, but a method in which the inorganic filler surface-treated with the coupling agent in advance by a dry or wet method is used is preferable. By adopting this method, the characteristics of the inorganic filler can be more effectively expressed.

In addition, the inorganic filler may be used as a slurry in which the inorganic filler is dispersed in an organic solvent in advance, as necessary.

### ((E) Curing Accelerator)

The thermosetting resin composition of the present embodiment preferably further contains (E) a curing accelerator, although not particularly limited thereto.

Examples of the curing accelerator (E) include amine-based curing accelerators, imidazole-based curing accelerators, phosphorus-based curing accelerators, organometallic salts, acidic catalysts, and organic peroxides. In the present embodiment, imidazole-based curing accelerators are not classified as amine-based curing accelerators. As the curing accelerator, one type may be used alone, or two or more types may be used in combination. The curing accelerator is preferably an amine-based curing accelerator, an imidazole-based curing accelerator, or a phosphorus-based curing accelerator.

Examples of the amine-based curing accelerator include amine compounds having a primary to tertiary amino group, such as triethylamine, 4-aminopyridine, tributylamine, and dicyandiamide; and quaternary ammonium compounds.

Examples of the imidazole-based curing accelerator include imidazole compounds such as methylimidazole, phenylimidazole, 2-undecylimidazole, and isocyanate-masked imidazole (for example, an addition reaction product of hexamethylene diisocyanate resin and 2-ethyl-4-methylimidazole).

Examples of the phosphorus-based curing accelerator include tertiary phosphines such as triphenylphosphine; and quaternary phosphonium compounds such as a tri-n-butylphosphine addition reaction product of p-benzoquinone.

### (Content of Curing Accelerator (E))

In a case where the thermosetting resin composition of the present embodiment contains the curing accelerator (E), the content thereof is not particularly limited, but in any case, the content is preferably 0.01 to 3 parts by mass, more preferably 0.05 to 2.5 parts by mass, still more preferably 0.1 to 2.5 parts by mass, and particularly preferably 0.5 to 2.3 parts by mass with respect to 100 parts by mass of the total amount of the resin components in the thermosetting resin composition. When the content of the curing accelerator (E) is within the above range, more favorable high-frequency characteristics, heat resistance, storage stability, and moldability tend to be obtained.

### ((F) Flame Retardant)

The thermosetting resin composition of the present embodiment preferably further contains (F) a flame retardant, although not particularly limited thereto.

Examples of the flame retardant (F) include inorganic phosphorus-based flame retardants; organic phosphorus-based flame retardants; and metal hydrates such as a hydrate of aluminum hydroxide and a hydrate of magnesium hydroxide. In addition, the metal hydroxide can also correspond to the inorganic filler, but in the case of a metal hydroxide capable of imparting flame retardancy, the metal hydroxide is classified as a flame retardant. Among these, as the flame retardant (F), an organic phosphorus-based flame retardant is preferable.

Examples of the organic phosphorus-based flame retardant include an aromatic phosphate ester, a phosphonate diester, and a phosphinate ester; a metal salt of phosphinic acid, an organic nitrogen-containing phosphorus compound, and a cyclic organophosphorus compound. Here, examples of the “metal salt” include lithium salts, sodium salts, potassium salts, calcium salts, magnesium salts, aluminum salts, titanium salts, and zinc salts. Among these, an aromatic phosphate ester is preferable as the organic phosphorus-based flame retardant.

### (Content of Flame Retardant (F))

In a case where the thermosetting resin composition of the present embodiment contains the flame retardant (F), the content thereof is not particularly limited, but in any case, the content is preferably 0.1 to 30 parts by mass, may be 1 to 25 parts by mass, may be 3 to 20 parts by mass, and may be 7 to 15 parts by mass with respect to 100 parts by mass of the total solid content in the thermosetting resin composition. When the content of the flame retardant (F) is equal to or greater than the lower limit value, more favorable flame retardancy tends to be obtained. When the content of the flame retardant (F) is equal to or less than the upper limit value, more favorable moldability, adhesiveness to a conductor, and more excellent heat resistance tend to be obtained.

(Content of Components Other than the Above-Described Components)

In a case where the thermosetting resin composition of the present embodiment contains components other than the above-described components (a flame retardant aid, an antioxidant, an adhesiveness improving agent, a heat stabilizer, an antistatic agent, an ultraviolet absorber, a pigment, a colorant, a lubricant, and other components), the content of each component is not particularly limited, but is, for example, 0.01 parts by mass or more, and may be 10 parts by mass or less, may be 5 parts by mass or less, may be 1 part by mass or less, or may not be contained with respect to 100 parts by mass of the total amount of the resin components of the thermosetting resin composition.

### (Organic Solvent)

The thermosetting resin composition of the present embodiment may be a so-called “varnish” containing an organic solvent from the viewpoint of facilitating handling and from the viewpoint of facilitating production of a prepreg to be described later.

Examples of the organic solvent include, but are not particularly limited to, alcohol-based solvents such as ethanol, propanol, butanol, methyl cellosolve, butyl cellosolve, and propylene glycol monomethyl ether; ketone-based solvents such as acetone, methyl ethyl ketone, methyl isobutyl ketone, and cyclohexanone; ether-based solvents such as tetrahydrofuran; aromatic solvents such as toluene, xylene, and mesitylene; nitrogen atom-containing solvents such as dimethylformamide, dimethylacetamide, and N-methylpyrrolidone; sulfur atom-containing solvents such as dimethyl sulfoxide; and ester-based solvents such as γ-butyrolactone. From the viewpoint of solubility, ketone-based solvents are preferable, and methyl isobutyl ketone is more preferable. The organic solvent can be used alone or in combination of two or more types.

In a case where the thermosetting resin composition of the present embodiment is used as a varnish, the solid content concentration is set to preferably 30 to 90% by mass, more preferably 40 to 80% by mass, and still more preferably 55 to 70% by mass. When the solid content concentration of the thermosetting resin composition is within the above range, the handling property of the thermosetting resin composition becomes easy, the impregnation property into a base material and the appearance of a prepreg to be produced become good, and the coating property at the time of forming a resin film also becomes good.

The thermosetting resin composition of the present embodiment can be produced by mixing the component (A), the component (B), and the components that can be used as necessary by a known method. At this time, the respective components may be dissolved or dispersed in the organic solvent while stirring. Conditions such as mixing order, temperature, and time are not particularly limited, and can be arbitrarily set.

Since the thermosetting resin composition of the present embodiment can exhibit a high dielectric constant (Dk) and a low dielectric dissipation factor (Df), the thermosetting resin composition is useful for an antenna module, in particular, for a miniaturized antenna module corresponding to the fifth generation mobile communication system (5G).

### [Prepreg]

The prepreg of the present embodiment is a prepreg containing the thermosetting resin composition of the present embodiment or a semi-cured product of the thermosetting resin composition. Since the prepreg of the present embodiment can exhibit a high dielectric constant (Dk) and a low dielectric dissipation factor (Df), the prepreg is useful for an antenna module, in particular, for a miniaturized antenna module corresponding to 5G.

The prepreg of the present embodiment contains, for example, the thermosetting resin composition of the present embodiment or a semi-cured product of the thermosetting resin composition and a sheet-shaped fiber base material. The prepreg is formed using the thermosetting resin composition of the present embodiment and the sheet-shaped fiber base material, and can be obtained, for example, by impregnating or coating the thermosetting resin composition of the present embodiment into the sheet-shaped fiber base material, drying, and semi-curing (B-staging) the product as necessary. More specifically, for example, the prepreg of the present embodiment can be produced by semi-curing (B-staging) by heating and drying usually at a temperature of 80 to 200° C. for 1 to 30 minutes in a drying furnace. Here, in the description herein, B-staging is to bring into a B-stage state as defined in JIS K6900 (1994).

The amount of the thermosetting resin composition to be used can be appropriately determined for the purpose of setting the solid content concentration derived from the thermosetting resin composition in the prepreg after drying to 30 to 90% by mass. In a case where the solid content concentration is set to be in the above-described range, better moldability tends to be obtained when a laminate is formed.

As the sheet-shaped fiber base material of the prepreg, known ones used for various laminates for electrical insulating materials can be used. Examples of the material of the sheet-shaped fiber base material include inorganic fibers such as E glass, D glass, S glass, and Q glass; organic fibers such as polyimide, polyester, and tetrafluoroethylene; and mixtures thereof. These sheet-shaped fiber base materials have a shape of, for example, a woven fabric, a nonwoven fabric, a roving, a chopped strand mat, or a surfacing mat.

The thickness of the prepreg is not particularly limited and may be 10 to 170 μm, may be 10 to 120 μm, or may be 10 to 70 μm.

### [Resin Film]

The resin film of the present embodiment is a resin film containing the thermosetting resin composition of the present embodiment or a semi-cured product of the thermosetting resin composition. Since the resin film of the present embodiment can exhibit a high dielectric constant (Dk) and a low dielectric dissipation factor (Df), the resin film is useful for an antenna module, in particular, for a miniaturized antenna module corresponding to 5G.

The resin film of the present embodiment can be produced, for example, by applying a thermosetting resin composition containing an organic solvent, that is, a varnish, to a support, heating and drying the varnish, and semi-curing (B-staging) the varnish as necessary.

Examples of the support include a plastic film, a metal foil, and a release paper.

The drying temperature and the drying time may be appropriately determined according to the amount of the organic solvent to be used, the boiling point of the organic solvent to be used, and the like, but the resin film can be suitably formed by drying at 50 to 200° C. for about 1 to 10 minutes.

### [Laminate]

The laminate of the present embodiment is a laminate having a cured product of the thermosetting resin composition of the present embodiment or a cured product of the prepreg of the present embodiment, and a metal foil. Since the laminate has a high dielectric constant (Dk) and a low dielectric dissipation factor (Df), the laminate is useful for an antenna module, particularly for a miniaturized antenna module corresponding to 5G.

The laminate of the present embodiment can be produced, for example, by disposing a metal foil on one surface or both surfaces of a prepreg obtained by stacking two or more sheets of the prepreg of the present embodiment, or disposing a metal foil on one surface or both surfaces of a prepreg obtained by stacking a total of two or more sheets of the prepreg of the present embodiment and a prepreg other than the present embodiment, and then performing heating press molding. In the laminate obtained by the production method, the prepreg of the present embodiment is in C-staging. In the description herein, C-staging is to bring into a C-stage state as defined in JIS K6900 (1994). A laminate having a metal foil is sometimes referred to as a metal-clad laminate.

The metal of the metal foil is not particularly limited, but from the viewpoint of conductivity, the metal may be copper, gold, silver, nickel, platinum, molybdenum, ruthenium, aluminum, tungsten, iron, titanium, chromium, or an alloy containing one or more of these metallic elements, and is preferably copper or aluminum, more preferably copper.

The conditions of the heating press molding are not particularly limited, but the heating press molding can be carried out, for example, at a temperature of 100 to 300° C., a pressure of 0.2 to 10 MPa, and a time of 0.1 to 5 hours. In addition, a method of maintaining a vacuum state for 0.5 to 5 hours using a vacuum press can be adopted for the heating press molding.

### [Printed Wiring Board]

The printed wiring board of the present embodiment has one or more selected from the group consisting of a cured product of the thermosetting resin composition of the present embodiment, a cured product of the prepreg, and the laminate of the present embodiment. The printed wiring board of the present embodiment can be produced by using one or more selected from the group consisting of the prepreg of the present embodiment, the resin film of the present embodiment, and the laminate of the present embodiment, and performing circuit formation processing by drilling, metal plating, etching of a metal foil, or the like by a known method. In addition, a multilayer printed wiring board can be produced by further performing multilayer adhesion processing as necessary. In the printed wiring board of the present embodiment, the prepreg of the present embodiment or the resin film of the present embodiment is in C-staging.

### [Antenna Device]

The present disclosure also provides an antenna device having the laminate or the printed wiring board of the present embodiment. The antenna device may be provided with one laminate, or may be provided with a plurality of laminates or printed wiring boards. The way of installing the plurality of antenna elements is not particularly limited, but it is preferable to arrange them in a two-dimensional array, for example. The configuration of the antenna device is not particularly limited, and for example, JP 6777273 B can be referred to.

In consideration of use for an antenna module, the laminate or the printed wiring board in the antenna device preferably has a conductor pattern such as a feeding conductor pattern, a grounding conductor pattern, and a short-circuiting conductor. The short-circuiting conductor is a conductor that short-circuits the feeding conductor pattern and the grounding conductor pattern, and is provided in a via hole portion described below.

The conductor pattern is preferably formed of a metal containing copper, aluminum, gold, silver, and an alloy thereof as a main component.

It is preferable that the laminate or the printed wiring board in the antenna device has a via hole. The via hole makes it possible to form the short-circuiting conductor, and makes it possible to conduct the feeding conductor pattern and the grounding conductor pattern.

The method for forming the via hole is not particularly limited, and a method such as laser, plasma, or a combination thereof can be used. As the laser, a carbon dioxide gas laser, a YAG laser, a UV laser, an excimer laser, or the like can be used.

After the formation of the via hole, for example, a desmearing treatment using an oxidizing agent may be performed. The oxidizing agent is preferably a permanganate such as potassium permanganate or sodium permanganate; a dichromate; ozone; hydrogen peroxide-sulfuric acid; or nitric acid, more preferably a permanganate, and still more preferably an aqueous sodium hydroxide solution of a permanganate, that is, a so-called alkaline permanganate aqueous solution.

It is preferable that the laminate or the printed wiring board in the antenna device is formed with a short-circuiting conductor in the via hole after the formation of the via hole. The conductor used herein is preferably formed of the same metal as that of the metal forming the conductor pattern.

### [Antenna Module]

The present disclosure also provides an antenna module including a feeding circuit and the antenna device of the present embodiment. The feeding circuit is not particularly limited, but an RFIC (Radio Frequency Integrated Circuit) or the like can be used. The RFIC includes a switch, a power amplifier, a low-noise amplifier, an attenuator, a phase shifter, a signal synthesizer/demultiplexer, a mixer, and an amplifier circuit.

A high-frequency signal supplied from the RFIC is transmitted to the feeding point of the feeding conductor via a short-circuiting conductor formed in a via of the laminate for antenna module.

The configuration of the antenna module is not particularly limited, and for example, JP 6777273 B can be referred to.

### [Communication Device]

Furthermore, the present disclosure also provides a communication device including a baseband signal processing circuit and the antenna module of the present embodiment.

The communication device of the present embodiment can upconvert the signal transmitted from the baseband signal processing circuit to the antenna module to a high-frequency signal and radiate the high-frequency signal from the antenna device, and can downconvert the high-frequency signal received by the antenna device to process the signal in the baseband signal processing circuit.

Although preferred embodiments have been described above, these are examples for describing the present disclosure, and the scope of the present disclosure is not limited to these embodiments. The present disclosure may include various aspects different from the embodiment without departing from the gist of the present disclosure.

### EXAMPLES

Hereinafter, the present embodiment will be specifically described with reference to Examples. However, the present embodiment is not limited to the following Examples.

In each Example, the weight-average molecular weight (Mw) was measured by the following method.

### (Measurement Method of Weight-Average Molecular Weight (Mw))

By gel permeation chromatography (GPC), the weight-average molecular weight was converted from a calibration curve using standard polystyrene. The calibration curve was approximated by a cubic equation using standard polystyrene: TSK standard POLYSTYRENE (Type; A-2500, A-5000, F-1, F-2, F-4, F-10, F-20, F-40) [manufactured by Tosoh Corporation, trade name]. The measurement conditions of GPC are shown below.

### Apparatus:

Pump: L-6200 type (manufactured by Hitachi High-Tech Corporation)
Detector: L-3300 type RI (manufactured by Hitachi High-Tech Corporation)
Column oven: L-655A-52 (manufactured by Hitachi High-Tech Corporation)
Column: guard column; TSK Guardcolumn HHR-L+column; TSKgel G4000HHR+
TSKgel G2000HHR (all manufactured by Tosoh Corporation, trade names) Column size: 6.0×40 mm (guard column), 7.8× 300 mm (column)
Eluent: tetrahydrofuran
Sample concentration: 30 mg/5 ml
Injection volume: 20 μL
Flow rate: 1.00 mL/min
Measurement temperature: 40° C.

The particle size distribution of the component (B) and the component (B′) used in each Example was measured by the following method.

### (Method for Measuring Particle Size Distribution)

In a Potter type homogenizer (volume: 10 cm³), 0.15 g of the component (B) or (B′) and 0.1 mL of sodium hexametaphosphate were introduced, and the mixture was pulverized for 1 minute. Then, the pulverized mixture was added to 50 ml of water filtered through a 1 μm filter, and the mixture was treated for 3 minutes in an ultrasonic bath. The mixture was used as a sample for evaluation.

Using 5 to 10 mL of the samples for evaluation prepared above, the particle size distribution was measured using a particle size distribution measuring apparatus “Microtrac MT3300EXII” (manufactured by MicrotracBEL Corp.). Water (containing 0.1% by mass of sodium hexametaphosphate) was used as a measurement solvent, and the measurement was performed in a transmission mode for a measurement time of 30 seconds. The measurement was performed twice, and the average value of the two measurements was defined as the particle size distribution of the component (B) or the component (B′) contained in the sample for evaluation.

### Production Example 1: Production of Modified Maleimide Compound

100 parts by mass of 2,2-bis [4-(4-maleimidophenoxy)phenyl]propane, 5.6 parts by mass of a siloxane compound having amino groups at both terminals (functional group equivalents 750 g/mol), 7.9 parts by mass of 3,3′-diethyl-4,4′-diaminodiphenylmethane, and 171 parts by mass of propylene glycol monomethyl ether were introduced into a reaction vessel having a volume of 5 L, capable of heating and cooling, equipped with a thermometer, a stirrer, and a water titrator with a reflux condenser, and reacted for 2 hours while refluxing. The resultant was concentrated at a reflux temperature over 3 hours to produce a modified maleimide compound solution having a solid content concentration of 65% by mass. The weight-average molecular weight (Mw) of the obtained modified maleimide compound was about 2,700.

### Examples 1 and 2, Comparative Examples 1 to 3

Each component described in Table 1 was stirred and mixed at room temperature with 58 parts by mass of toluene and 10 parts by mass of methyl isobutyl ketone according to the blending composition described in Table 1 to prepare a thermosetting resin composition (varnish) having a solid content concentration of 60 to 65% by mass, and the thermosetting resin composition was filtered using a nylon mesh of #200 mesh (mesh size: 75 μm) to obtain a filtrate. During the filtration, in Comparative Examples 1 to 3, clogging occurred and the filtration stopped. Therefore, the filtrate was obtained by pressing or mixing with a spatula from above during the filtration. Separately, in Comparative Examples 1 to 3, the solid content concentration of the varnish was lowered to 45% by mass, and filtration was attempted, but clogging similarly occurred in this case as well.

The resulting filtrate was coated on a 0.08 mm thick glass cloth (E Glass, manufactured by Nitto Boseki Co., Ltd.) and heat-dried at 150° C. for 5 minutes to prepare a prepreg having a solid content derived from the thermosetting resin composition of about 47% by mass. Low-profile copper foils (BF-ANP18, Rz of M surface: 1.5 μm, manufactured by CIRCUIT FOIL Co., Ltd.) having a thickness of 18 μm were disposed on the upper and lower sides of the prepreg so that the M surface (matte surface) was in contact with the prepreg, and then they were subjected to heating press molding under the conditions of a temperature of 230° C., a pressure of 3.0 MPa and a time of 90 minutes to produce a double-sided copper-clad laminate (thickness: 0.10 mm).

Using the varnish or double-sided copper-clad laminate obtained in each Example, each evaluation was performed according to the following methods. The results are shown in Table 1.

### [Evaluation of Varnish]

### (1. Mesh Passability)

As described above, the varnish obtained in each Example was filtered using a nylon mesh of #200 mesh (mesh size: 75 μm). At this time, the state of filtration was visually observed without any change, and evaluated according to the following evaluation criteria.
A: Clearly filtered.
C: Clogging occurred and filtration stopped.

### (2. Storage Stability)

The varnish obtained in each Example was placed in a vessel having a volume of 1 L and allowed to stand at 25° C. for 1 day. The varnish after standing for one day was visually observed for the state while appropriately shaking the vessel, and evaluated according to the following evaluation criteria.
A: Liquid, not gelled.
C: Gelled.

### [Evaluation of Double-Sided Copper-Clad Laminate]

### (3. Solder Heat Resistance)

A test piece obtained by cutting the double-sided copper-clad laminate obtained in each Example into a square with four sides of the 50 mm was floated in a solder bath at 288° C. and allowed to stand for 30 minutes. The surface of the test piece was visually observed, and the time (unit: second) until blisters occurred on the surface of the test piece was measured.

### (4. High-Frequency Characteristics)

The outer layer copper foils of the double-sided copper-clad laminate obtained in each Example were removed by dipping in a copper etching solution (10% by mass ammonium persulfate solution, manufactured by Mitsubishi Gas Chemical Company, Inc.), and the test piece cut to a length of 60 mm and a width of 2 mm was used as a test piece, and the dielectric constant (Dk) and the dielectric dissipation factor (Df) were measured by a cavity resonator perturbation method. Note that a vector type network analyzer “N5227A” manufactured by Agilent Technologies, Inc. was used as a measuring instrument, a cavity resonator “CP129” (10 GHz band resonator) manufactured by Kanto Electronics Application & Development Inc. was used as a cavity resonator, and a measurement program “CPMA-V2” was used as a measurement program. The measurement was performed under the conditions of a frequency of 10 GHz and a measurement temperature of 25° C.

TABLE 1

| | | | | Examples | | Comparative Examples | | |
|---|---|---|---|---|---|---|---|---|
| | | | Unit | 1 | 2 | 1 | 2 | 3 |
| Blending | (A) Thermosetting resin | A-1 | Parts by mass | 23 | 21 | 23 | 23 | 23 |
| composition | | A-2 | | 3 | 3 | 3 | 3 | 3 |
| | (B) High dielectric | B-1 | Parts by mass | 34 (15) | | | | |
| | constant inorganic filler | B-2 | (% by volume) | | 39 (15) | | | |
| | (B′) Comparative high | B′-3 | | | | 34 (15) | | |
| | dielectric constant | B′-4 | | | | | 34 (15) | |
| | inorganic filler | B′-5 | | | | | | 34 (15) |
| | (C) Elastomer | C-1 | Parts by mass | 5 | 4 | 5 | 5 | 5 |
| | (D) Inorganic filler | D-1 | Parts by mass | 27 (22) | 25 (22) | 27 (22) | 27 (22) | 27 (22) |
| | | | (% by volume) | | | | | |
| | (E) Curing accelerator | E-1 | Parts by | 0.5 | 0.5 | 0.5 | 0.5 | 0.5 |
| | | E-2 | mass*¹ | 0.5 | 0.5 | 0.5 | 0.5 | 0.5 |
| | | E-3 | | 0.78 | 0.78 | 0.78 | 0.78 | 0.78 |
| | (F) Flame retardant | F-1 | Parts by mass | 8 | 8 | 8 | 8 | 8 |

| | | | | | | |
|---|---|---|---|---|---|---|
| Evaluation | Mesh passability (mesh size 75 μm) | A | A | C | C | C |
| results | Storage stability (1 day, 25° C.) | A | A | A | C | C |
| | Solder heat resistance | 600 | 500 | 600 | <1 | <1 |
| | Dielectric constant Dk (10 GHz) | 6.0 | 7.1 | 6.0 | 6.0 | 6.0 |
| | Dielectric dissipation factor Df (10 GHz) | 0.0052 | 0.0060 | 0.0052 | 0.0052 | 0.0052 |

*¹Content with respect to 100 parts by mass of the total amount of the resin components of the thermosetting resin composition.
In each of Examples and Comparative Examples, the volume ratio of each component is the same.

Each component described in Table 1 will be described below.

### [(A) Thermosetting Resin]

A-1: Modified maleimide compound obtained in Production Example 1
A-2: Polyphenylene ether having methacryloyl groups at both molecular terminals (weight-average molecular weight: 1,700)

### [(B) High Dielectric Constant Inorganic Filler]

B-1: Calcium titanate
(content of particles having a particle diameter of 1.0 μm or less; about 21% by volume, content of particles having a particle diameter of 1.0 μm; about 3.1% by volume, average particle diameter (d50); about 2.1 μm)
B-2: Strontium titanate
(content of particles having a particle diameter of 1.0 μm or less; about 22% by volume, content of particles having a particle diameter of 1.0 μm; about 4.3% by volume, average particle diameter (d50); about 1.6 μm)

### [(B′) Comparative High Dielectric Constant Inorganic Filler]

B′-3: Calcium titanate
(content of particles having a particle diameter of 1.0 μm or less; about 35% by volume, content of particles having a particle diameter of 1.0 μm; about 4.2% by volume, average particle diameter (d50); about 1.3 μm)
B′-4: Calcium titanate
(content of particles having a particle diameter of 1.0 μm or less; about 61% by volume, content of particles having a particle diameter of 1.0 μm; about 3.2% by volume, average particle diameter (d50); about 0.8 μm)
B′-5: Calcium titanate
(content of particles having a particle diameter of 1.0 μm or less; about 65% by volume, content of particles having a particle diameter of 1.0 μm; about 2.0% by volume, average particle diameter (d50); about 0.5 μm)

### [(C) Elastomer: Styrene-Based Thermoplastic Elastomer]

C-1: Maleic anhydride-modified hydrogenated styrene-based thermoplastic elastomer (maleic anhydride-modified SEBS), acid value 10 mg CH₃ONa/g, styrene content 30%, MFR 5.0 g/10 min (measurement conditions of the MFR: measured under conditions of 230° C. and load 2.16 kg in accordance with ISO1133).

### [(D) Inorganic Filler]

D-1: Spherical fused silica: average particle diameter of 1.5 μm, 50% by mass slurry (solvent: toluene)

### [(E) Curing Accelerator]

E-1: 2-Undecylimidazole
E-2: Tri-n-butylphosphine addition reaction product of p-benzoquinone
E-3: Dicyandiamide

### [Flame Retardant]

F-1: Phosphate ester-based flame retardant having the following structural formula

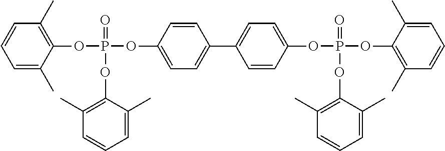 [SMILES: Cc1cccc(C)c1OP(=O)(Oc1ccc(-c2ccc(OP(=O)(Oc3c(C)cccc3C)Oc3c(C)cccc3C)cc2)cc1)Oc1c(C)cccc1C]

From the results of Table 1, in Examples 1 and 2, a high dielectric constant (Dk), a low dielectric dissipation factor (Df), and further high solder heat resistance were obtained, and a laminate useful for an antenna module was produced. It is found that the varnish prepared when the laminate was produced was excellent in the mesh passability and industrially practicable. Furthermore, it is found that the varnish is excellent in storage stability, which is industrially advantageous.

On the other hand, in Comparative Examples 1 to 3, the mesh passability of the varnish is poor, and it is difficult to industrially carry out the production of the laminate. In Comparative Examples 2 to 3, the storage stability of the varnish was also poor, and the heat resistance of the laminate was also low.

1. A thermosetting resin composition comprising:
(A) a thermosetting resin; and
(B) at least one inorganic filler selected from the group consisting of a titanium-based inorganic filler and a zircon-based inorganic filler,
wherein in the component (B), a content of particles having a particle diameter of 1.0 μm or less is 30% by volume or less based on the component (B).

2. The thermosetting resin composition according to claim 1, wherein a content of particles having a particle diameter of 1.0 μm in the component (B) is 4.5% by volume or less based on the component (B).

3. The thermosetting resin composition according to claim 1, wherein the component (B) has an average particle diameter of 1.0 μm or more.

4. The thermosetting resin composition according to claim 1, wherein the titanium-based inorganic filler is at least one selected from the group consisting of titanium dioxide and a metal titanate.

5. The thermosetting resin composition according to claim 4, wherein the metal titanate is at least one selected from the group consisting of an alkali metal titanate, an alkaline earth metal titanate, and lead titanate.

6. The thermosetting resin composition according to claim 1, wherein the zircon-based inorganic filler is an alkali metal zirconate.

7. The thermosetting resin composition according to claim 1, wherein the content of the component (B) is 1 to 60% by volume with respect to the total solid content in the thermosetting resin composition.

8. The thermosetting resin composition according to claim 1, wherein the component (A) contains at least one selected from the group consisting of an epoxy resin, a maleimide compound, a polyphenylene ether resin, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

9. The thermosetting resin composition according to claim 1, wherein the component (A) contains a polyphenylene ether resin having ethylenically unsaturated bond-containing groups at both terminals.

10. A prepreg comprising the thermosetting resin composition according to claim 1 or a semi-cured product of the thermosetting resin composition.

11. A resin film comprising the thermosetting resin composition according to claim 1 or a semi-cured product of the thermosetting resin composition.

12. A laminate comprising a cured product of the thermosetting resin composition according to claim 1, and a metal foil.

13. A printed wiring board comprising one or more selected from the group consisting of a cured product of the thermosetting resin composition according to claim 1.

14. An antenna device comprising the laminate according to claim 12.

15. An antenna module comprising a feeding circuit, and the antenna device according to claim 14.

16. A communication device comprising a baseband signal processing circuit and the antenna module according to claim 15.
